(19) United States
(12) Patent Application Publication
(10) Pub. No.: US 2025/0279401 A1
(43) Pub. Date: Sep. 4, 2025

(54) INTEGRATED MODULE HAVING A THERMAL NETWORK

(71) Applicant: TEXAS INSTRUMENTS INCORPORATED, DALLAS, TX (US)

(72) Inventors: JONATHAN MONTOYA, DALLAS, TX (US); SOMBUDDHA CHAKRABORTY, REDWOOD CITY, CA (US); OSVALDO LOPEZ, ANNADALE, NJ (US); Hidetoshi Inoue, Tochigi-Ken (JP); KENJI OTAKE, KARUIZAWA (JP)

(21) Appl. No.: 18/591,859

(22) Filed: Feb. 29, 2024

(51) Int. Cl. H01L 25/16; H01L 21/48; H01L 21/56; H01L 23/00; H01L 23/31; H01L 23/367; H01L 23/552

(52) U.S. Cl. CPC H01L 25/16; H01L 21/4821; H01L 21/4871; H01L 21/565; H01L 23/3121; H01L 23/367; H01L 23/552; H01L 24/32; H10D 1/20; H01L 2224/32225; H01L 2924/19011; H01L 2924/19042

(57) ABSTRACT

One example includes an electronic circuit package. The electronic circuit package includes a lead frame. The electronic circuit package includes an electronic circuit die disposed on the lead frame. The electronic circuit package includes an integrated inductor. The electronic component package includes a heat sink structure to provide a thermally conductive path for heat to rise to the distal surface of the electronic component package in relation to the electronic circuit die. The electronic component package includes a molding material that provides additional thermal conductivity for the electronic component package in relation to the electronic circuit die.

### TECHNICAL FIELD

The present disclosure relates generally to electronic component packages, and more particularly to an integrated module having a thermal network.

### BACKGROUND

Withdrawing the heat from an integrated circuit is desirable to improve the performance of the circuit and to prevent damage to the circuit and surrounding components. Integrated circuit chips can be cooled by passing a flow of cooling fluid through a cold plate in close proximity to remove heat from an integrated circuit. Air cooling integrated circuits in controlled climate environments can be employed to reduce the heat from the integrated circuit. Heat sinks can be coupled to the integrated circuit to remove heat.

Discrete inductors can make component routing very dense and complex for traces to meet clearance and spacing requirements. Unlike integrated circuits that host many components onto a single chip, discrete circuits have space restriction and are bulky and heavy. Routing and component placement can determine electromagnetic compatibility against unwanted noise, otherwise known as electromagnetic interference.

### SUMMARY

The following is a brief summary of subject matter that is described in greater detail herein. This summary is not intended to be limiting as to the scope of the claims.

In a first example, an electronic component package includes a lead frame. The electronic component package includes an electronic circuit die having a first surface that is in contact with the lead frame and a second surface opposite the first surface. The electronic component package includes an integrated inductor. The integrated inductor includes at least one inductor element electrically coupled to the electronic circuit die. The electronic component package includes a heat sink structure formed over the second surface of the electronic circuit die, the heat sink structure comprising at least one side portion extending from the second surface of the electronic circuit die and a distal surface relative to the electronic circuit die via at least the distal surface. The electronic component package includes a molding material covering the electronic circuit die, the integrated inductor and at least a portion of the heat sink structure.

According to a second example, a method of forming an electronic component package includes forming a lead frame. The method of forming an electronic component package includes forming an electronic circuit die having a first surface that is in contact with the lead frame and a second surface opposite the first surface. The method of forming an electronic component package includes forming at least one inductor element of an integrated inductor on the electronic circuit die. The method of forming an electronic component package includes forming a heat sink structure over the second surface of the electronic circuit die, the heat sink structure comprising at least one side portion extending from the second surface of the electronic circuit die and a distal surface relative to the electronic circuit die, the distal surface being parallel with and offset from the second surface of the electronic circuit die by the at least one side portion to dissipate heat from the electronic circuit die via at least the distal surface. The method of forming an electronic component package includes depositing a molding material on the electronic circuit die, the integrated inductor and at least a portion of the heat sink structure.

### BRIEF SUMMARY OF THE DRAWINGS

The general inventive concepts, as well as illustrative examples and advantages thereof, are described below in greater detail, by way of example, with reference to the drawings in which:

FIG. 1 illustrates a diagram of an electronic component package.

FIG. 2 illustrates a perspective view of a circuit having integrated conductive pads.

FIG. 3 illustrates a perspective view of an electronic component package comprising a thermal network and an integrated inductor in an offset configuration.

FIG. 4 illustrates a perspective view of an electronic component package comprising a thermal network and an integrated inductor in a stacked configuration.

FIG. 5 illustrates a perspective view of a fabricated electronic component package.

FIG. 6 illustrates a perspective view of an electronic component package comprising an alternate configuration of a thermal network.

FIG. 7 illustrates a perspective view on an alternate example of a fabricated electronic component package.

FIG. 8 illustrates an example of a flow diagram for forming an electronic component package.

### DETAILED DESCRIPTION

The present disclosure relates generally to electronic component packages, and more particularly to an integrated module having a thermal network. As described herein, a heat sink structure is of particular significance with respect to the reduction of heat in the active circuitry of the electronic component package, including an integrated inductor. As described herein, the integrated inductor is formed by at least one inductor element and ferromagnetic materials suspended in an associated molding material that covers at least a portion of the electronic component package. As described herein, the formation of the heat sink structure provides improvements in the dissipation of heat through a distal portion of the electronic component package in relation to the circuit die.

As an example, the electronic component package described herein includes a heat sink to act as a thermal network within the electronic component package to dissipate heat from the circuit die to the housing portion of the electronic component package. The heat sink structure can include at least one side portion extending from a surface of the electronic circuit die, such as from a die plate coupled to the surface of the electronic circuit die. The heat sink structure also includes a distal surface relative to the electronic circuit die. The heat sink can thus dissipate heat via at least the distal surface. In one example, the heat sink structure can be formed on the surface of the lead frame surrounding the electronic circuit die in an enclosure configuration that has a hollow interior and at least partially encloses the electronic circuit die. The heat sink structure can include at least one sidewall portion extending away from the circuit die that interconnects the distal surface and the circuit die (e.g., a die plate coupled to the circuit die). As an example, the enclosure structure can include at least two sidewalls, such that the distal surface connects the sidewalls. As an example, the distal surface in the enclosure configuration can have a plurality of perforations to aid in the forming of a molding material on the electronic component package. In another example, the heat sink structure can be formed as a solid block over the circuit die for ease of production, resource efficiency, and for applications configured for enhanced heat dissipation. In an example, an integrated inductor can be formed on the surface of the circuit die adjacent to the heat sink structure in an offset configuration. In one example, one or more surfaces (e.g., the distal surface) of the heat sink structure can be exposed from the molding material to the ambient environment. The formation of the heat sink structure improves the dissipation of heat, thereby mitigating instability in the circuit die.

The process of forming the electronic component package including the heat sink structure and the integrated inductor, as described herein, includes forming the heat sink structure on the surface of the circuit die, such as including a die plate. In the enclosure configuration, the sidewall(s) can be formed as vertical wall portions, and the distal surface can be formed as coupled to an end of the sidewall(s) opposite the circuit die. The distal surface can be formed to include perforation holes spanning the distal surface to allow flow-through of the molding material. In another example, the heat sink can be formed as a solid slug of thermally conductive material directly over the circuit die. A molding compound can be deposited over and/or through the heat sink structure, at least one inductor element, and the circuit die to form an electronic component package with the improved ability to dissipate heat through the distal portion of the package in relation to the circuit die.

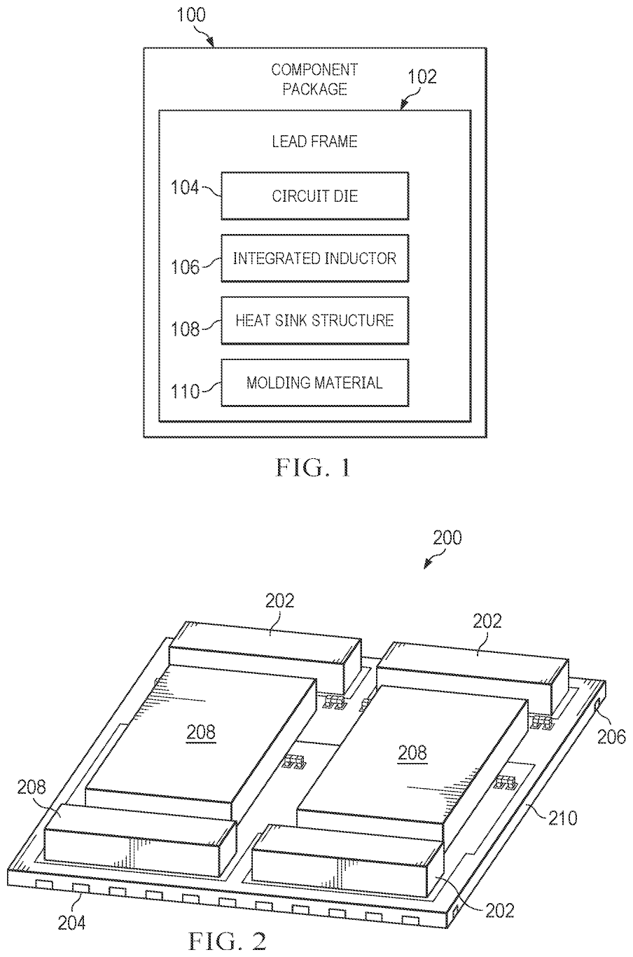

Referring to FIG. 1, a block diagram of an electronic component package 100 in accordance with the disclosure is depicted. The electronic component package 100 includes a lead frame 102, a circuit die 104, an integrated inductor 106, a heat sink structure 108, and a molding material 110 including ferromagnetic material therein forming a housing body. The circuit die 104 can comprise a first surface in contact with the lead frame 102 and a second surface opposite the first surface. As an example, the integrated inductor 106 can be arranged as an overpass structure having a pillar at a first side of the circuit die 104 and a pillar at a second side of the circuit die 104 and an inductor portion connecting the pillars. For example, the molding material 110 can include suspended ferromagnetic materials, such that the integrated inductor 106 can cooperate with the molding material 110 to be a magnetic molded compound (MMC) inductor. The heat sink structure 108 can be formed over the second surface of the circuit die 104. The heat sink structure 108 can comprise at least one side portion extending from the second surface of the circuit die 104 and a distal surface relative to the circuit die 104. The distal surface can be parallel with and offset from the second surface of the circuit die 104 to dissipate heat from the circuit die 104 via at least the distal surface of the electronic component package 300. In an example, the heat sink structure 108 can be configured as an enclosure having one or more sidewalls extending vertically from the lead frame 102 of the electronic circuit package 100 and a connecting portion connecting the sidewall(s). In another example, the heat sink structure 108 can be configured as a solid block above the circuit die 104. As an example, the electronic component package 100 of the present disclosure can be mounted in a system requiring heat to be dissipated through the surface distal to the circuit die 104 or at least one side surface of the electronic component package 100.

The circuit die 104 can be configured as a semiconductor (e.g., silicon) device that includes active devices (e.g., metal oxide semiconductor (MOS) transistors, diodes, silicon controlled rectifiers (SCRs), etc.) In one example, the circuit die 104 can be mounted on a die attach pad that is part of the lead frame 102 using a die attach compound. In another example, the circuit die 104 can be provided on circuit mounts electrically connected to the lead frame 102.

The circuit die 104 can be aligned (e.g., substantially flush) with the surface of the lead frame 102. One or more discrete components can protrude from the circuit die 104. Alternatively, the components can be flush with the surface of the circuit die 104. In an example, the circuit die 104 can be configured to cover a portion of the lead frame 102. The circuit die 104 can include a single die or multiple dies mounted on the lead frame 102.

The circuit die 104 can be provided on the internal surface of the lead frame 102 in the electronic component package 100. The integrated inductor 106 can be configured on a conductive pad of the lead frame 102 in electrical communication with the circuit die 104. The integrated inductor 106 can be configured as an integrated component of the electronic component package 100 to maximize the space in which the electronic component package 100 is residing. The integrated inductor 106 extends in a direction approximately perpendicular to the circuit die 104. The circuit die 104 can be positioned on the lead frame 102 directly beneath the inductor portion of the integrated inductor 106. In another example, the integrated inductor 106 can be adjacent to the circuit die 104 and the heat sink structure 108 whereby the circuit die 104 and the heat sink structure 108 can be positioned on an adjacent portion of the lead frame 102 from the integrated inductor 106.

In one example, the integrated inductor 106 can include one or more inductor elements formed on the lead frame 102. For example, the integrated inductor 106 can include two inductor elements, each for a separate power phase, to provide a multi-phase inductor. The integrated inductor 106 can be coupled to its respective conductive pads on the lead frame 102 forming a stacked arrangement above the circuit die 104. One or more conductive features (e.g., die pads, thermal pads, etc.) can be soldered to the surface of the lead frame 102 to form electrical and thermal connections therewith. In another example, the conductive pads can be formed by a metallization process or other additive manufacturing processes. Each conductive pad can contain discrete components (e.g., resistors, capacitors, and other components) separate from the circuit die 104. The electronic component package 100 includes electrically and thermally conductive metal features of the lead frame 102, one or more of which provide thermal heat removal from the electronic component package 100.

The circuit die 104 is thermally coupled to a heat sink structure 108 to dissipate excess thermal energy. The heat sink structure 108 can be significantly larger in height than the circuit die 104 in order to dissipate enough heat per given time specifically in a direction perpendicular to the circuit die. The heat sink structure 108 absorbs heat energy from the surface of the circuit die 104 and draws heat to the distal surface of the electronic component package 100 in relation to the circuit die 104, resulting in higher heat sink efficiency.

The heat sink structure 108 can include a die plate (not shown) that can be provided in close proximity above the circuit die 104. The die plate is configured to draw heat from the circuit die 104 and provide a thermally conductive path to the heat sink structure 108 for dissipation of heat to the distal surface of the electronic component package 100 in relation to the circuit die 104. The die plate can include a first surface facing the circuit die 104 and a second surface opposite the first surface. The die plate can be integrally formed to the circuit die 104. The die plate can be attached to the circuit die 104 by any suitable wafer bonding techniques. The die plate and the heat sink structure 108 can be integrally formed, or can be bonded together at a heat absorbing junction thereby yielding a heat sink/spreader structure.

Turning now to FIG. 2, a circuit 200 having a plurality of conductive pads 202 for the integrated inductor is shown. The conductive pads 202 can be provided to allow an integrated inductor (not shown) to be a surface mount device mounted directly to the surface of the lead frame 210. Surface mount inductors can be rectangular in shape. Electrically conductive terminals on one or more portions of the conductive pads 202 can be exposed for connections to contacts on the lead frame 210. By positioning a first conductive pad 202 at a first end of the lead frame 204 and a second conductive pad 202 at a second end of the lead frame 206, an integrated inductor can be provided whereby allowing surface space for additional circuitry to reside on the lead frame 210.

In the effort of saving space and increasing reliability, an integrated inductor can be installed on the conductive pads 202 using suitable manufacturing techniques, wherein a first pillar of the integrated inductor is coupled to the first conductive pad 202 and the second pillar of the integrated inductor is coupled to the second conductive pad 202. The resulting integrated inductor has a smaller footprint than an inductor having a conventional winding.

The inductor mounts 202 are boxed shaped module structures with a circuit die 212 disposed between adjacent conductive pads 202. A variety of circuit components (e.g., resistors, capacitors, etc.) can be mounted to supporting surfaces of the circuit die 208 and the inner portion of the conductive pads 202. Electrically conductive paths are provided on the circuit die 208 surfaces and on the inner surfaces of the conductive pads 202. During fabrication of the lead frame 210, the surface can be etched or electroplated to form conductive traces. Interface contacts or terminals can be provided on the bottom surface of the lead frame 210 for making electrical connections to contacts with external devices. The conductive pads 202 can be sufficiently wide to permit stable connection of the integrated inductor to the lead frame 210 in a generally orthogonal orientation.

The conductive pads 202 can be surface mount soldered to the lead frame 210. A thermally conductive material can be used to couple the integrated inductor and the lead frame 210 while leaving contacts of the lead frame 210 exposed. A thermally conductive material can be provided on a surface of the circuit die 208.

The reduction in the footprint of the integrated inductor over the lead frame 210 may be attributable to the reduction in area required on the lead frame 210 by traditional components of the circuit die 208. The integrated inductor enables more efficient utilization of the area on the lead frame 210, and can thus enable use in compact devices including high current applications that generate more heat.

In an example, a thermal network comprising the heat sink structure is utilized to maintain the temperature of the circuit die 208 by transferring the heat to the distal surface of the device in relation to the circuit die 208. In this way the temperature of the circuit die 208 may not surpass the optimal temperature range simply by operating in a common state of high demand. In another example, the thermal network can be utilized to coincide with an optimal temperature range in which the circuit die 208 would by itself operate in a state of low or moderate demand and to facilitate the direction in which the heat is transferred.

The thermal network comprising the heat sink structure can be utilized with signal processing circuitry, I/O circuitry, processing circuitry, control circuitry, memory circuitry, antenna circuitry, or any other circuitry in an electronic device. In other words, the circuit die 208 can take the form of any of the circuitry described above or any other circuitry that benefits from the use of the thermal network in any way. Areas further away from the circuit die can be heated less than areas closer to the heat source. The temperature of the circuit die 208 can depend in part on the surface area of the heat sink and the position of the heat source in relation to the circuit die 208 on the lead frame 210.

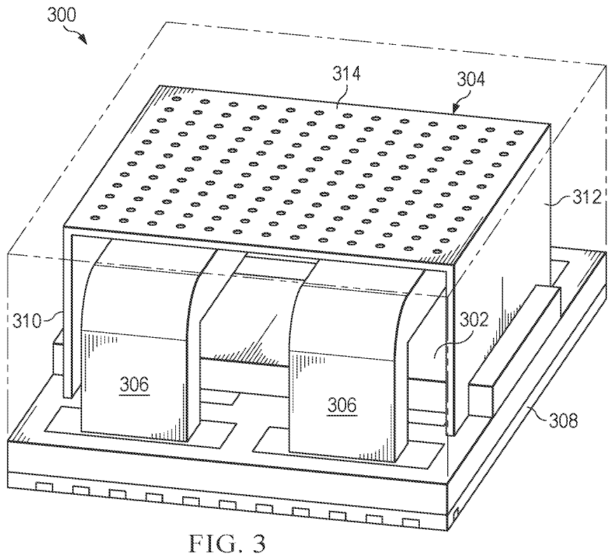

Turning now to FIG. 3, an electronic component package 300 comprising a thermal network and an integrated inductor in a stacked configuration is shown. A thermally conductive die plate 302 can be provided above the surface of the circuit die (not shown) in close proximity to transfer heat conduction produced by the circuit die. The die plate 302 can be thermally coupled to the heat sink structure 304 to draw the heat produced by the circuit die to the distal surface of the electronic component package 300 in relation to the circuit die. The integrated inductor 306 can also conduct heat during processes performed by the circuit die. The heat conducted by the integrated inductor 306 can be transferred to the heat sink structure 304 to maintain optimal performance of the electronic component package 300. An epoxy molding layer can be deposited on the surface of the lead frame 308 of the electronic component package 300 to assist in the curing of a mold housing comprising ferromagnetic material that will be described in further detail below in the description of FIG. 5.

The die plate 302 is a segment of substantially planar thermally conductive material that can be provided substantially perpendicular to the heat sink structure 304. However, examples can also include any shaped heat spreader or other features that may improve thermal regulation of the electronic component package 300. The die plate 302 is disposed over the circuit die having the bottom surface of the die plate 302 facing the component mount surface of the circuit die. The die plate 302 is in direct contact with the heat sink structure 304 to provide a path of heat conduction from the circuit die to the distal surface of the electronic component package 300 in relation to the circuit die.

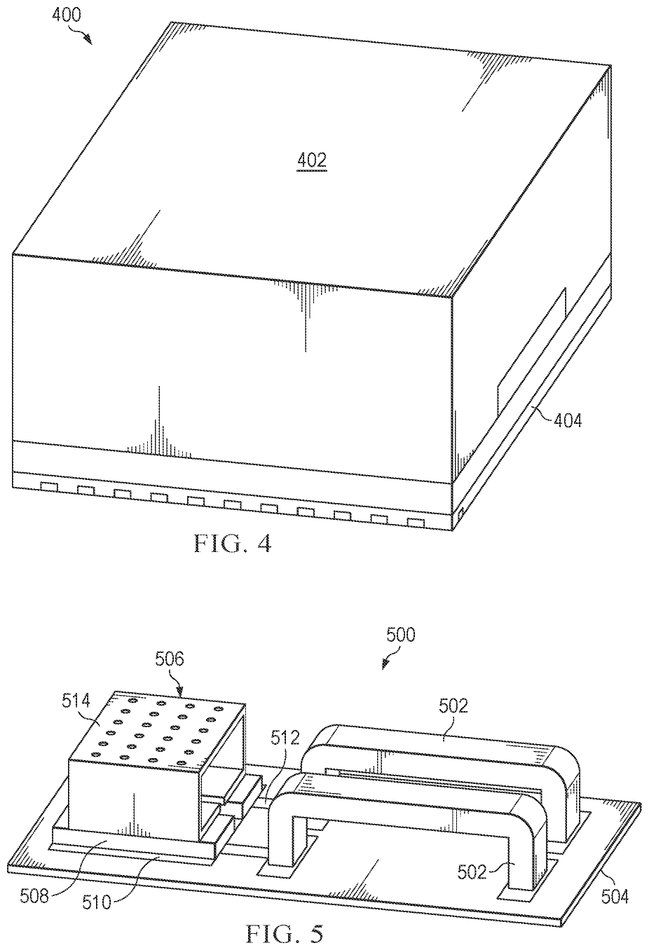

In an example, the heat sink structure 304 can be a first sidewall 310 and a second sidewall 312 provided on opposite ends of the lead frame 308 formed from any suitable thermally conductive material. The sidewalls 310 and 312 of the heat sink structure 304 can have a generally flat surface. A distal portion 314 connecting the sidewalls 310 and 312 can be provided to increase the surface area of the heat sink structure 304 which can facilitate a direction of flow of thermal conductivity towards the distal surface of the electronic component package 300 in relation to the circuit die. The distal portion 314 can be formed to include perforations, whereby aiding in the deposit of a molding material as described in FIG. 4 as described in further detail below. In various examples, the sidewalls 310 and 312 can be of various sizes and shapes and can be disposed on the surface of the lead frame 308 in a variety of configurations. In an example, one or more of the sidewalls 310 and 312 and/or the distal portion 314 can be arranged exterior to the molding material, and thus can be at least partially exposed to the ambient environment. In another example, the sidewalls 310 and 312 of the heat sink structure 304 can extend upwards from the die plate 302 having no contact with the lead frame 308.

The integrated inductor 306 can be provided within the electronic component package 300 to obviate the need for a discrete inductor, whereby reducing the space needed for the circuitry in an electronic device and/or system. The integrated inductor 306 can be a heat source during active operation of the electronic component package 300. The heat sink structure 304 can draw the heat from the integrated inductor 306 to the distal surface of the electronic component package 300 in relation to the circuit die.

The integrated inductor 306 can be disposed on and in electrical and thermal contact with the lead frame 308. In an example, the integrated inductor 306 can be disposed on conductive pads as described above in FIG. 2. The use of a magnetic mold compound can allow for increased performance of the integrated inductor 306.

In an example, the die plate 302 can be provided above the surface of the circuit die to transfer heat to the heat sink structure comprising the first sidewall 310 and the second sidewall 312. While the example of FIG. 3 demonstrates two sidewall portions 310 and 312, in other examples, the heat sink structure can include one sidewall portion or more than two sidewall portions that extend between the circuit die 302 and the distal surface 314. The sidewalls (310, 312) can be of various sizes and shapes and can be disposed on the surface of the die plate 302 in a variety of configurations.

Turning now to FIG. 4, a fabricated electronic component package 400 is shown. The arrangement is formed with the purpose of providing efficient and highly integrated heat transfer through the distal surface of the electronic component package 400 in relation to the circuit die (not shown). The electronic component package 400 can be used in a variety of applications, such as power supplies, sensors, driver integrated circuits, indicators, control panels, and the like. A magnetic molding material 402 comprising ferromagnetic material objects suspended therein can be provided to the top portion of the electronic component package 400. The inductor element(s) and the ferromagnetic material objects can collectively correspond to the integrated inductor. An isolation mold layer can be deposited on the lead frame 404 covered with an isolation laminate material which can provide protection for the active circuitry of the circuit die.

The isolation mold layer enables the active circuitry of the electronic component package 400 to have isolation between circuits. The isolation mold layer can be deposited on the surface of the lead frame 404 during the manufacturing of the electronic component package 400. The isolation mold layer can be disposed on and in thermal contact with the surface of the lead frame 404, thereby shielding the circuit die from the magnetic molding material 402. However, in another example, the isolation mold layer can be deposited on a portion of the lead frame 404 or not at all depending on the needs of the active circuitry.

The magnetic molding material 402 can include a molding compound, a molding underfill, an epoxy, or a resin. The molding material having ferromagnetic objects (e.g., flakes, spheres, etc.) to provide for a portion of the operation of the integrated inductor can be deposited to the electronic component package 300 as described in FIG. 3 to form a solid unit as shown in FIG. 4 without voids. Thermal energy can be conducted into and out of the distal surface of the electronic component package 400 in relation to the circuit die.

Turning now to FIG. 5, an electronic component package 500 comprising a thermal network and an integrated inductor in an offset configuration is shown. An integrated inductor 502 can be provided on the lead frame 504 adjacent to the heat sink structure 506. The heat sink structure 506 can be formed in thermal communication with one or more die plates 508 to dissipate heat from the circuit die 510 towards a distal surface of the heat sink structure 506 in relation to the lead frame 504. The integrated inductor 502 can be in electrical communication with the circuit die 510 via a plurality of conductive traces 512.

The heat sink structure 506 can include a distal portion 514 configured to conjoin the sidewalls of the heat sink structure 506. In one example, the distal portion 514 of the heat sink structure 506 can include a plurality of through holes to aid in the deposit of a molding material as described below in FIG. 4. During the manufacturing of the electronic component package 500, the molding material can flow through the holes in the distal portion 514 of the heat sink structure 506 in a liquid form and later cured to a solid form without the formation of voids. As one example, the distal surface of the electronic component package 500 can correspond to the distal portion 514 between the sidewalls of the heat sink structure. The sidewalls of the heat sink structure 506 can be arranged in parallel with each other and forming a hollow volume therebetween.

In an example, the electronic circuit die 510 can be formed on a first portion of the lead frame 504 adjacent to a second portion of the lead frame 504 having the integrated inductor 502 formed thereon. The integrated inductor 502 can be formed by a pair of inductor elements arranged in a parallel configuration. The integrated inductor 502 comprising a pair of inductor elements can allow the deposit of the molding material to flow throughout the electronic circuit package and forming without voids.

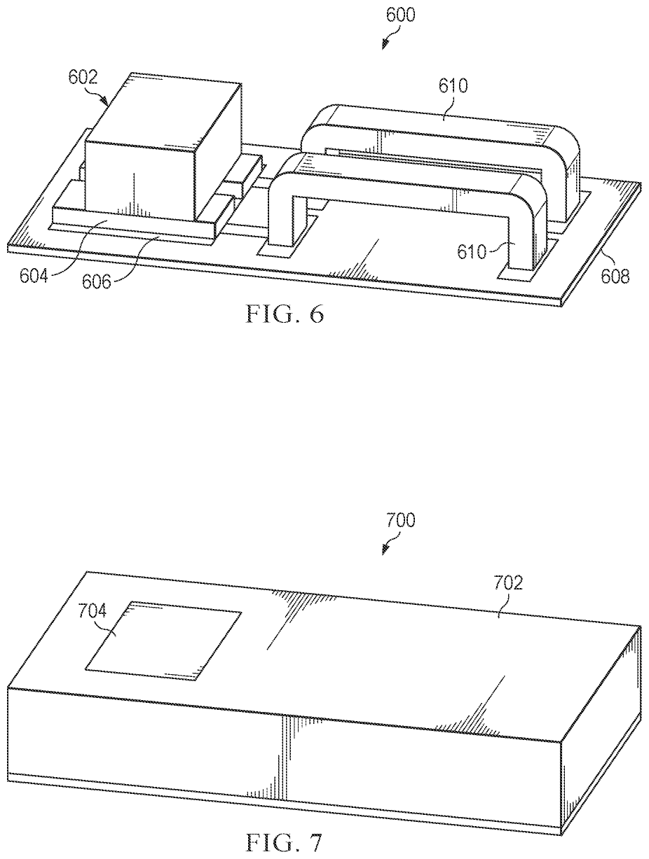

Turning now to FIG. 6, an electronic component package 600 comprising an alternate configuration of a thermal network is shown. A heat sink structure 602 can be formed in a solid block configuration. The heat sink structure 602 can be integrally formed on one or more die plates 604, or can be bonded together at a heat absorbing junction thereby yielding a heat sink/spreader structure. The electronic component package 600 can be configured to comprise a circuit die 606 having a first surface in contact with the lead frame 608 second surface opposite the first surface.

In an example, the heat sink structure 602 can be formed over the second surface of the electronic circuit die 606, the heat sink structure 602 comprising at least one side portion extending from the second surface of the electronic circuit die 606 and a distal surface relative to the electronic circuit die 606, the distal surface being parallel with and offset from the second surface of the electronic circuit die 606 by the at least one side portion to dissipate heat from the electronic circuit die 606 via at least the distal surface. In one example, the integrated inductor 610 can be formed adjacent to the heat sink structure 602 on the lead frame 608. The integrated inductor 610 can be in electrical communicate with the electronic circuit die via one or more conductive traces.

Turning now to FIG. 7, an alternate example of a fabricated electronic component package 700 is shown. The electronic component package 700 can be formed including a thermal network at least partially accessible to the immediate surroundings of the electronic component package 700. In an example, the molding material 702 can be provided in a configuration whereby at least a portion of at least one of the sidewalls and/or of the distal portion of the heat sink structure 704 can be exposed to the ambient environment. The exposed heat sink structure 704 can be provided to further direct the dissipation of heat as needed for system requirements. The exposed heat sink structure 704 is demonstrated as or similar to the heat sink structure 602 in the example of FIG. 6 that is formed as a solid block, such that at least one of the surfaces of the exposed solid-block heat sink structure 704 is exposed to the ambient environment. As another example, the exposed heat sink structure 704 can correspond to the heat sink structure 506 in the example of FIG. 5 that is formed as having parallel sidewalls connected by a distal surface to define a hollow volume therebetween, such that at least one of the surfaces of the exposed hollow heat sink structure is exposed to the ambient environment.

The foregoing outlines features of several examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the examples introduced herein. Those skilled in the art should also realize that such equivalent constructions do not depart from the spirit and scope of the present disclosure, and that they may make various changes, substitutions, alterations herein without departing from the spirit and scope of the present disclosure.

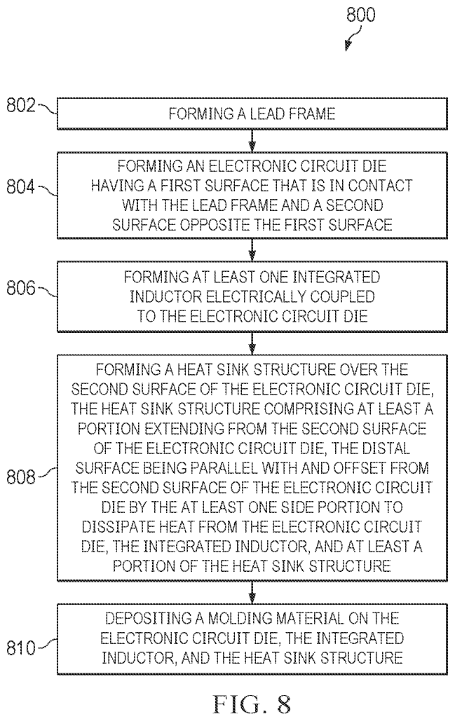

Referring now to the example of FIG. 8, illustrated is a flow diagram 800 for forming an electronic component package in accordance with one or more examples described herein.

At 802, the flow diagram comprises forming a lead frame.

At 804, the flow diagram comprises forming an electronic circuit die having a first surface that in contact with the lead frame and a second surface opposite the first surface.

At 806, the flow diagram comprises forming at least one integrated inductor electrically coupled to the electronic circuit die.

At 808, the flow diagram comprises forming a heat sink structure formed over the second surface of the electronic circuit die, the heat sink structure comprising at least one side portion extending from the second surface of the electronic circuit die and a distal surface relative to the electronic circuit die, the distal surface being parallel with and offset from the second surface of the electronic circuit die by the at least one side portion to dissipate heat from the electronic circuit die via at least the distal surface.

At 810, the flow diagram comprises depositing a molding material on the electronic circuit die, the integrated inductor, and at least a portion of the heat sink structure.

The forming an electronic component package further includes forming a die plate on at least a portion of the lead frame and positioned above the electronic circuit die, wherein the die plate is thermally coupled to the heat sink structure to provide a thermally conductive path from the electronic circuit die to the heat sink structure.

The forming an electronic component package further includes forming the integrated inductor adjacent to the heat sink structure on the lead frame in an offset configuration.

The forming an electronic component package further includes forming an isolation layer on at least a portion of the lead frame to protect the electronic circuit die from electromagnetic interference.

The forming an electronic component package further includes forming a die plate on at least a portion of the lead frame and positioning the die plate above the surface of the electronic circuit die.

The forming an electronic component package further includes forming a plurality of conductive pads, each of the conductive pads comprising one or more discrete components, on the lead frame, wherein the integrated inductor is coupled to a pair of conductive pads of the plurality of conductive pads for electrical communication with the electronic circuit die.

The forming an electronic component package includes a first integrated inductor element of a pair of integrated inductor elements is formed on a first pair of conductive pads of the plurality of conductive pads and a second integrated inductor element of the pair of integrated inductor elements is formed on a second pair of conductive pads of the plurality of conductive pads, wherein the first integrated inductor element of the pair of integrated inductor elements is formed in parallel with the second integrated inductor element of the pair of integrated inductor elements.

The forming an electronic component package includes exposing at least a portion of the heat sink structure to the ambient environment.

The forming an electronic component package includes a distal portion of the vertically rising heat sink connecting a first sidewall portion at a first side of the lead frame to a second sidewall portion at a second side of the lead frame, wherein the connecting portion comprises a plurality of perforations.

The forming an electronic component package includes the heat sink structure being formed as a solid block.

The forming an electronic component package includes the molding material comprising ferromagnetic objects to form part of the integrated inductor.

The foregoing detailed description is merely illustrative and is not intended to limit examples and/or application or uses of examples. Furthermore, there is no intention to be bound by any expressed or implied information presented in the preceding Background or Summary sections, or in the Detailed Description section.

As used in the specification and the appended claims, the singular forms “a,” “an,” and “the” are intended to include the plural forms as well, unless the context clearly indicates otherwise.

Unless otherwise indicated, any element, property, feature, or combination of elements, properties, and features, may be used in any example disclosed herein, regardless of whether the element, property, feature, or combination was explicitly disclosed in the example. It will be readily understood that features described in relation to any particular aspect described herein may be applicable to other aspects described herein provided the features are compatible with that aspect. In particular, features described herein in relation to the method may be applicable to the electronic component package product and vice versa.

Reference throughout this specification to “one example,” or “an example,” means that a particular feature, structure, or characteristic described in connection with the example is included in at least one example. Thus, the appearances of the phrase “in one example,” “in one aspect,” or “in an example,” in various places throughout this specification are not necessarily all referring to the same example. Furthermore, the particular features, structures, or characteristics may be combined in any suitable manner in one or more examples.

The words “exemplary” and/or “demonstrative” are used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, such terms are intended to be inclusive-in a manner similar to the term “comprising” as an open transition word-without precluding any additional or other elements.

The above description includes non-limiting aspects of the various examples. It is, of course, not possible to describe every conceivable combination of components or methods for purposes of describing the disclosed subject matter, and one skilled in the art may recognize that further combinations and permutations of various examples are possible. The disclosed subject matter is intended to embrace all such alterations, modifications, and variations that fall within the spirit of the appended claims.

With regard to the various functions performed by the above described components, the terms (including a reference to a “means”) used to describe such components are intended to also include, unless otherwise indicated, any structure(s) which performs the specified function of the described component (e.g., functional equivalent), even if not structurally equivalent to the disclosed structure. In addition, while a particular feature of the disclosed subject matter may have been disclosed with respect to only one of several implementations, such feature may be combined with one or more features of the other implementations as may be desired and advantageous for any given or particular applications.

The terms “exemplary” and/or “demonstrative” as used herein are intended to mean serving as an example, instance, or illustrative. For the avoidance of doubt, the subject matter disclosed herein is not limited to such examples. In addition, any aspect or design described herein as “exemplary” and/or “demonstrative” is not necessarily to be construed as preferred or advantageous over the other aspects or designs, nor is it meant to preclude equivalent structures and techniques known to one skilled in the art. Furthermore, to the extent that the terms “includes,” “has,” “contains,” and other similar words are used in either the detailed description or the claims, such terms are intended to be inclusive-in a manner similar to the term “comprising” as an open transition word-without precluding any additional or other elements.

What is claimed is:

1. An electronic component package comprising:
a lead frame;
an electronic circuit die having a first surface in contact with the lead frame and a second surface opposite the first surface;
an integrated inductor, the integrated inductor comprising at least one inductor element electrically coupled to the electronic circuit die;
a heat sink structure formed over the second surface of the electronic circuit die, the heat sink structure comprising at least one side portion extending from the second surface of the electronic circuit die and a distal surface relative to the electronic circuit die, the distal surface being parallel with and offset from the second surface of the electronic circuit die by the at least one side portion to dissipate heat from the electronic circuit die via at least the distal surface; and
a molding material covering the electronic circuit die, the at least one inductor element, and at least a portion of the heat sink structure.

2. The electronic component package of claim 1, further comprising:
a die plate formed on at least a portion of the electronic circuit die, wherein the die plate is thermally coupled to the heat sink structure to provide a thermally conductive path from the electronic circuit die to the heat sink structure.

3. The electronic component package of claim 1, wherein the at least one inductor element is formed adjacent to the heat sink structure on the lead frame in an offset configuration.

4. The electronic component package of claim 1, wherein an isolation layer is formed on at least a portion of the lead frame to protect one or more active circuits of the electronic circuit die from electromagnetic interference.

5. The electronic component package of claim 1, further comprising:
a plurality of conductive pads, each of the conductive pads comprising one or more discrete components, formed on the lead frame, wherein the at least one inductor element is coupled to a respective at least one pair of the conductive pads for electrical communication with the electronic circuit die.

6. The electronic component package of claim 5, wherein the at least one inductor element comprises a first integrated inductor element formed on a first pair of conductive pads of the plurality of conductive pads and a second integrated inductor element formed on a second pair of conductive pads of the plurality of conductive pads, wherein the first integrated inductor element is formed in parallel with the second integrated inductor element.

7. The electronic component package of claim 1, wherein at least a portion of the heat sink structure is exposed to an ambient environment.

8. The electronic component package of claim 1 sidewall, wherein the distal surface of the heat sink structure comprises a plurality of perforations to facilitate flow-through of the molding material.

9. The electronic component package of claim 1, wherein the heat sink structure is formed as a solid block.

10. The electronic component package of claim 1, wherein the integrated inductor comprises the at least one inductor element and ferromagnetic objects suspended in the magnetic material.

11. A method of forming an electronic component package, the method comprising:
forming a lead frame;
forming an electronic circuit die having a first surface that is in contact with the lead frame and a second surface opposite the first surface;
forming at least one inductor element on the electronic circuit die;
forming a heat sink structure formed over the second surface of the electronic circuit die, the heat sink structure comprising at least one side portion extending from the second surface of the electronic circuit die by the at least one side portion to dissipate heat from the electronic circuit die via at least the distal surface; and
depositing a molding material on the electronic circuit die, the at least one inductor element, and at least a portion of the heat sink structure.

12. The method of claim 11, further comprising:
forming a die plate on at least a portion of the electronic circuit die, wherein the die plate is thermally coupled to the heat sink structure to provide a thermally conductive path from the electronic circuit die to the heat sink structure.

13. The method of claim 15, further comprising:
forming the at least one inductor element adjacent to the heat sink structure on the lead frame in an offset configuration.

14. The method of claim 11, further comprising:
forming an isolation layer on at least a portion of the lead frame to protect the electronic circuit die from electromagnetic interference.

15. The method of claim 11, further comprising:
forming a plurality of conductive pads, each of the conductive pads comprising one or more discrete components, on the lead frame, wherein the at least one inductor element is coupled to a respective at least one pair of conductive pads for electrical communication with the electronic circuit die.

16. The method of claim 15, wherein the at least one inductor element comprises a first integrated inductor element formed on a first pair of conductive pads of the plurality of conductive pads and a second integrated inductor element formed on a second pair of conductive pads of the plurality of conductive pads, wherein the first integrated inductor element is formed in parallel with the second integrated inductor element.

17. The method of claim 11, wherein at least a portion of the heat sink structure is exposed to an ambient environment.

18. The method of claim 17, wherein the distal surface of the heat sink structure comprises a plurality of perforations to facilitate flow-through of the molding material.

19. The method of claim 11, wherein the heat sink structure is formed as a solid block.

20. The method of claim 11, wherein the integrated inductor comprises the at least one inductor element and ferromagnetic objects suspended in the magnetic material.
